(19) United States
(12) Patent Application Publication
(10) Pub. No.: US 2007/0202704 A1
(43) Pub. Date: Aug. 30, 2007

(54) Method for etching platinum and method for fabricating capacitor using the same

(75) Inventors: Su-Bum Shin, Kyoungki-do (KR); Hyun Ahn, Kyoungki-do (KR); Jung-Taik Cheong, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,644

(22) Filed: Dec. 29, 2006

(30) Foreign Application Priority Data
Feb. 28, 2006 (KR) 2006-0019654
Oct. 9, 2006 (KR) 2006-0097893

(51) Int. Cl. H01L 21/461; H01L 21/302

(52) U.S. Cl. 438/706; 257/E21.222

(57) ABSTRACT

A method for etching platinum (Pt) includes etching a platinum layer using a gas mixture including a fluorine (F) containing gas and an inert gas. A method for fabricating a capacitor having a bottom electrode, a dielectric layer, and an upper electrode includes forming the bottom electrode by etching a platinum layer, and forming the upper electrode by etching another platinum layer, wherein the platinum layers are etched using a gas mixture including a fluorine (F) containing gas and an inert gas.

### CROSS-REFERENCES TO RELATED APPLICATIONS

The present invention claims priority of Korean patent application numbers 10-2006-0019654 and 10-2006-0097893, filed on Feb. 28, 2006 and Oct. 9, 2006, respectively, which are incorporated by reference in their entirety.

### BACKGROUND OF THE INVENTION

The present invention relates to a method for fabricating a semiconductor device, and more particularly, to an etching method for forming a platinum (Pt) electrode.

Until recently, silicon dioxide (SiO₂) with a dielectric constant of approximately 3.9, oxide/nitride (ON), and oxide/nitride/oxide (ONO) with a dielectric constant ranging from approximately 7 to approximately 8 have been used as a dielectric layer for a capacitor in a memory device. However, such typical dielectric layers have become impractical due to the rapid decrease in the thickness of the dielectric layers. Thus, a material having a larger dielectric constant has been generally required.

A dielectric layer, that maintains a superior property of matter when an effective oxide thickness is less than 2 nm, and development of technology for fabricating such dielectric layer are generally needed to overcome the above-described technological barriers. Such dielectric layer includes lead-zirconate-titanate (PZT)-based and barium-strontium-titanate (BST)-based high-k dielectric layers. Limitations related to electrodes may be generated if such high-k dielectric thin layers are used as capacitor materials because characteristics of electrodes influence characteristics of capacitors.

The high-k dielectric thin layers are formed by employing one of a sputtering method and a chemical vapor deposition (CVD) method. Using silicon as an electrode material may result in an interfacial oxide layer, such as a SiO₂ layer, to form on surfaces since formation of the thin layers are performed in ambient oxygen, decreasing the dielectric constant value. Thus, silicon is generally needed to be replaced with a material that does not oxidize or that maintains conductivity even when oxidized. Research on dielectric layers as well as high-k dielectric thin layers have been actively pursued.

Forming bottom electrodes is important because a critical dimension (CD) of the bottom electrodes in dynamic random access memories (DRAM) determines the minimum critical dimension of the device. Thus, an etching technology that provides sufficient CD control, and at the same time, provides almost perpendicular-shaped form is usually required.

Recently, platinum has been used as an electrode material in capacitors. Platinum has a small specific resistance of approximately 1.05×10⁻⁴ Ω/cm², and thus, allows a superior operation speed characteristic of the device. Platinum is a high fusion point metal with thermal stability. Platinum is not easily oxidized, and thus, does not form an interfacial oxide layer. Platinum has superior properties for use as an electrode material of a BST-based high-k dielectric thin layer.

One of the advantages of a platinum electrode is that the platinum electrode has a larger work function of approximately 5.4 eV than other types of electrodes. Thus, a high surface potential barrier may be formed against a flow of electrons. PZT and BST are typically known to have P-type electric conductivity, but surfaces of PZT and BST are transformed to N-type. Thus, an energy barrier against electron movement is formed on the interface when the PZT-based and BST-based high-k dielectric layers come in contact with platinum, resulting in reduced leakage current.

A chlorine-based gas or plasma is usually used to etch platinum used as an electrode of a DRAM capacitor. That is, an etching process including physical sputtering is generally used. However, the following limitations may be generated when platinum is used as an electrode of a capacitor. Etched shape may be tapered or a fence may be generated on etched surfaces. Platinum is a chemically stable material and usually does not easily generate by-products of etching. Generated by-products are redeposited on etched surfaces due to low volatility, causing a fence and tapering.

FIG. 1A illustrates a micrographic view of a fence generated while etching platinum according to a typical method. FIG. 1B illustrates a micrographic view of tapering generated while etching platinum according to the typical method. Results shown in FIGS. 1A and 1B are obtained after etching platinum using a gas mixture including chlorine (Cl₂) and argon (Ar). Using the gas mixture including Cl₂/Ar to etch platinum causes surface roughness deterioration. Surface roughness plays an important role regarding electrode property when forming an electrode of a capacitor. Leakage current is generated at an interface between the electrode and a dielectric layer as the surface roughness increases, deteriorating device characteristics.

Generally, leakage current increases as electrons are captured by trap sites at an interface. The number of trap sites increases as surface roughness increases. Therefore, a smooth surface is very important with respect to the device characteristics. Using the gas mixture including Cl₂/Ar to etch platinum may result in a poor surface roughness value, causing leakage current. Platinum etched by the gas mixture including Cl₂/Ar may obtain increased surface roughness due to non-volatile materials deposited on surfaces.

### SUMMARY OF THE INVENTION

Embodiments of the present invention are directed to provide a method for etching platinum in a semiconductor device, with satisfactory surface roughness and without a fence and tapering.

In accordance with an aspect of the present invention, there is provided a method for etching platinum (Pt), including etching a platinum layer using a gas mixture including a fluorine (F) containing gas and an inert gas.

In accordance with another aspect of the present invention, there is provided a method for fabricating a capacitor having a bottom electrode, a dielectric layer, and an upper electrode, the method including: forming the bottom electrode by etching a platinum layer; and forming the upper electrode by etching another platinum layer, wherein the platinum layers are etched using a gas mixture including a fluorine (F) containing gas and an inert gas.

### BRIEF DESCRIPTION OF THE DRAWINGS

FIG. 1A illustrates a micrographic view of a fence generated while etching platinum according to a typical method.

FIG. 1B illustrates a micrographic view of tapering generated while etching platinum according to the typical method.

FIG. 2 illustrates a diagram showing a method for etching platinum in accordance with a specific embodiment of the present invention.

FIG. 3 illustrates a structural diagram of an etch apparatus used in a platinum etching process shown in FIG. 2.

FIG. 4A illustrates a graph showing etch rates of platinum according to various content levels of chlorine (Cl₂) in a gas mixture including Cl₂/argon (Ar)

FIG. 4B illustrates a graph showing etch rates of platinum according to various content levels of sulfur hexafluoride (SF₆) in a gas mixture including SF₆/Ar.

FIG. 5 illustrates a graph showing intensity of Ar ions and fluorine (F) radicals according to various content levels of SF₆ in a gas mixture including SF₆/Ar.

FIG. 6 illustrates a graph showing etch rate changes according to various pressure levels.

FIG. 7 illustrates a graph showing etch rates of platinum according to various microwave power levels.

FIG. 8 illustrates a graph showing etch rates of platinum according to various radio frequency (RF) power levels.

FIG. 9A illustrates a micrographic view of an etched surface of platinum using Cl₂/Ar gas.

FIG. 9B illustrates a micrographic view of an etched surface of platinum using SF₆/Ar gas.

FIG. 10A illustrates a graph showing surface roughness of platinum that is etched using a gas mixture including Cl₂/Ar.

FIG. 10B illustrates a graph showing surface roughness of platinum that is etched using a gas mixture including SF₆/Ar.

FIGS. 11A to 11C illustrate atomic force microscopic (AFM) views of etched platinum surfaces.

FIG. 12A illustrates a graph showing an X-ray photoelectron spectroscopy (XPS) spectrum of a platinum surface etched using a gas mixture including Cl₂/Ar.

FIGS. 12B and 12C illustrate graphs showing XPS spectrums of platinum surfaces etched using a gas mixture including SF₆/Ar.

FIG. 13 illustrates a cross-sectional view showing a method for forming a capacitor using platinum as a bottom electrode and an upper electrode in accordance with a specific embodiment.

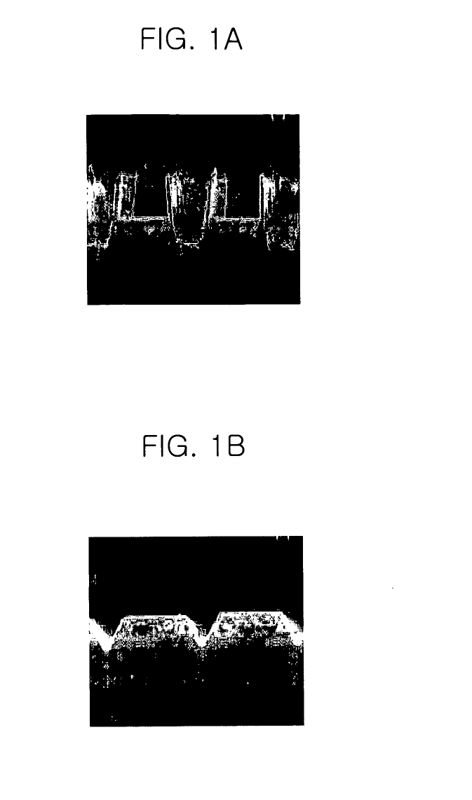

### DESCRIPTION OF SPECIFIC EMBODIMENTS

The present invention relates to a method for etching platinum and a method for fabricating a capacitor using the same. Platinum is etched using a gas mixture including sulfur hexafluoride (SF₆)/argon (Ar) to form a platinum fluoride compound having strong volatility. Consequently, an improved platinum pattern that does not generate a fence or tapering may be obtained.

Furthermore, using the gas mixture including SF₆/Ar allows obtaining platinum with improved surface roughness. A reliable capacitor having reduced leakage current may be obtained by employing the improved platinum as an electrode of the capacitor.

A typical method employs a physical sputtering to etch platinum using a chlorine-based plasma. However, in this specific embodiment, a gas including fluorine, e.g., SF₆ gas, is employed to induce chemical reaction with platinum, in another words, chemical etching of platinum, based on the fact that a platinum fluoride (PtF₆) compound has a boiling point at approximately 58° C. and that the PtF₆ compound can generate highly volatile by-products of etching.

Table 1 shows melting points of chlorine-based compounds and platinum fluoride compounds.

TABLE 1

| Compounds | Melting point (° C.) |
|---|---|
| IrCl₂ | 773 |
| IrCl₃ | 703 |
| IrF₆ | 44 |
| IrI₄ | 100 |
| PtBr₂ | 250 |
| PtCl₂ | 180 |
| PtCl₄ | 370 |
| PtCl₃ | 435 |
| PtF₆ | 58 |
| PtI₂ | 360 |
| PtI₄ | 130 |
| PtI₃ | 270 |

Accordingly Table 1, a compound including platinum and fluorine, i.e., platinum fluoride compound, has a much lower melting point than compounds including platinum and chlorine. Thus, the compound including platinum and fluorine has stronger volatility than the compounds including platinum and chlorine.

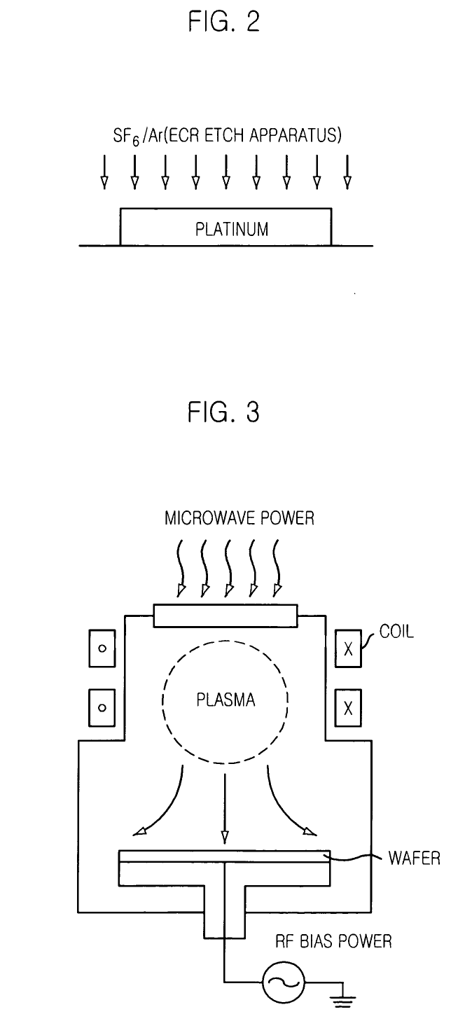

FIG. 2 illustrates a diagram showing a method for etching platinum in accordance with a specific embodiment of the present invention. A method for etching platinum includes forming a platinum layer over a semi-finished wafer. The wafer including the platinum layer is loaded in a chamber of an etch apparatus. An example of the etch apparatus includes an etch apparatus using an electron cyclotron resonance (ECR) method. The platinum layer is etched in the chamber using a gas mixture including SF₆ gas and Ar gas. SF₆ gas includes fluorine, and Ar gas is an inert gas. Levels of pressure, microwave power, and radio frequency (RF) bias power are adequately controlled while etching the platinum layer to obtain results with minimized fence and tapering. The gas mixture including SF₆ gas and Ar gas reacts with platinum during etching and generates volatile materials. Consequently, residues are hardly deposited on surfaces, and thus, surface roughness does not increase.

FIG. 3 illustrates a structural diagram showing an example of an etch apparatus used in the platinum etching process shown in FIG. 2. In particular, an etch apparatus using an ECR method is illustrated. The ECR method includes using a microwave power of approximately 2.45 GHz, forming a high density plasma by having the generated microwave resonant with a magnetic field of approximately 875 Gauss, and forming a magnetic field around the wafer using a substrate bias of approximately 13.56 MHz RF bias power. Pumps, microwave power generator, gas implanting line, and load rock chamber are abridged herein for convenience. While the etch apparatus using the ECR method is shown in this embodiment, other widely known structures may also be used. A system capable of independently controlling the microwave power and RF power is used. Thus, each variable is controlled to obtain optimum platinum etch characteristics.

Platinum may be etched utilizing the etch apparatus using the ECR method under the following conditions. A gas mixture including SF₆ gas and Ar gas is used. A flow rate ratio of SF₆ gas is approximately 50% of a total flow rate of the gas mixture. A pressure applied during the etching ranges from approximately 1 mTorr to approximately 5 mTorr. A microwave power ranges from approximately 700 W to approximately 1,200 W. A RF bias power ranges from approximately 100 W to approximately 150 W. The total flow rate of the gas mixture is approximately 8 sccm.

Etch rates of platinum with respect to the gas mixture including SF₆ gas and Ar gas consistent with this embodiment and a gas mixture including chlorine (Cl₂) and Ar consistent with a typical method are described below. An etch rate of platinum is approximately 150 Å/min when the gas mixture including SF₆ gas and Ar gas is used. On the contrary, an etch rate of platinum is approximately 60 Å/min or less when the gas mixture including Cl₂ and Ar is used. The etch rate of platinum using the gas mixture including SF₆ gas and Ar gas is approximately 2.5 times higher than the etch rate of platinum using the gas mixture including Cl₂ and Ar.

The highest etch rate results when a flow rate ratio of Cl₂ is approximately 50% of a total flow rate ratio of the gas mixture including Cl₂ and Ar. The etch rate decreases when higher flow rate ratios of Cl₂ are used. Chlorine (Cl) radicals react with platinum to generate non-volatile materials, i.e., PtClₓ, when a large quantity of Cl₂ is added to the gas mixture. Such non-volatile materials are deposited on etched surfaces of platinum and interrupt etching, producing a fence, tapering, and increased surface roughness. For instance, the non-volatile materials may include PtCl₂, PtCl₄, and PtCl₃.

Platinum may not be etched using argon gas solely in the system of the etch apparatus using ECR method. Thus, the etch rate of platinum does not increase even when a large quantity of argon is added to the etch gas. Ar gas may not have a direct effect on the etching of platinum. Generally, Ar gas is known to contribute to physical etching. The etch rate of platinum may not be increased when only a physical sputtering is used.

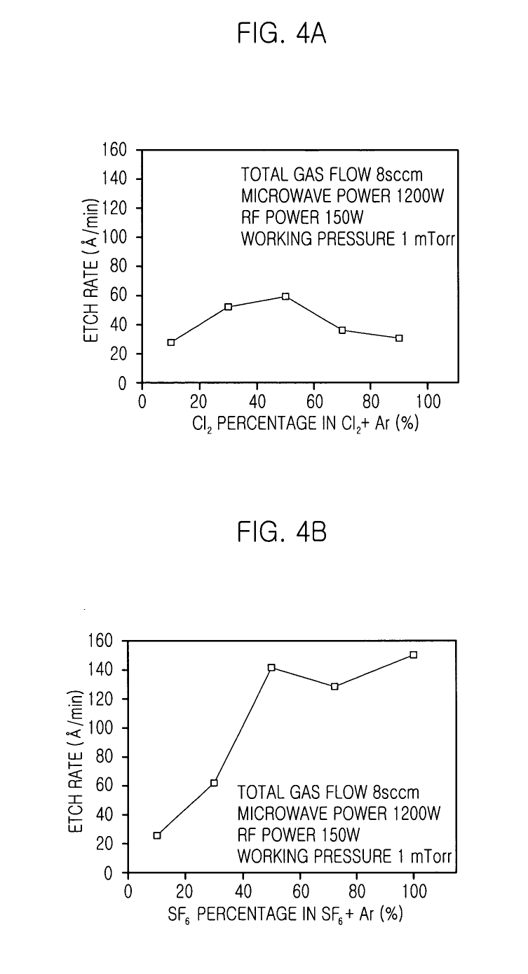

FIG. 4A illustrates a graph showing etch rates of platinum according to various content levels of chlorine (Cl₂) in a gas mixture including Cl₂/argon (Ar). FIG. 4B illustrates a graph showing etch rates of platinum according to various content levels of sulfur hexafluoride (SF₆) in a gas mixture including SF₆/Ar. The etch rate of platinum increases as the content level of SF6 gas increases. As more SF₆ gas is added to the gas mixture, platinum fluoride compounds with volatility are formed and the etch rate increases. Such estimation can be derived from changes in intensity of Ar ions and fluorine (F) radicals according to feeding ratios of the gas mixture including SF₆/Ar shown through a plasma analysis using an optical emission spectroscopy (OES).

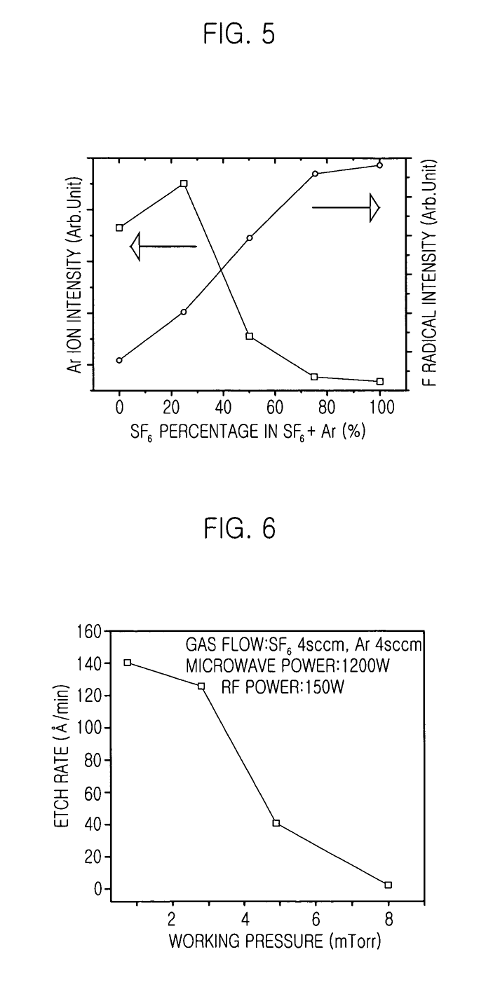

FIG. 5 illustrates a graph showing intensity of Ar ions and F radicals according to various content levels of SF₆ in a gas mixture including SF₆/Ar. As a quantity of SF₆ gas increases in the gas mixture including SF₆/Ar, the intensity of F radicals increases and the intensity of Ar ions decreases. Ar ions physically damage surfaces of platinum, and help F radicals to react on damaged sites and become activated. Thus, the etch rate increases.

When a feeding ratio of the gas mixture including SF₆/Ar is less than approximately 50%, that is, when Ar gas has a larger flow rate than SF₆ gas in the gas mixture, the intensity of Ar ions increases and the intensity of F radicals decreases substantially. Thus, chemical etching decreases and the total etch rate decreases accordingly. On the contrary, when a feeding ratio of the gas mixture including SF₆/Ar is more than approximately 50%, that is, when SF₆ gas has a larger flow rate than Ar gas in the gas mixture, the intensity of Ar ions decreases and the intensity of F radicals increases. Thus, chemical etching increases and the total etch rate increases accordingly. Chemical etching is generally required to be predominant when etching platinum, rather than physical etching.

FIG. 6 illustrates a graph showing etch rate changes according to various pressure levels. Generally, as a pressure increases, a temperature of electrons decreases and collisions of particles in a plasma increase. The speed of a dissociation process increases in the plasma and density of reactivity radicals and atoms increases. As a result, chemical etch rate increases. However, an ionization process is restrained when the pressure increases, resulting in decreased ion density and a decreased sheath potential difference between the plasma and an electrode. A reduced mean free path generates a diffusion effect, and thus, ion energy accelerating to a substrate surface decreases. As illustrated, the reduced mean free path causes density of ions having sufficient energy for sputtering platinum to decrease at a pressure of approximately 5 mTorr or higher. By-products of etching are not discharged smoothly out of the chamber, and thus, the etch rate decreases.

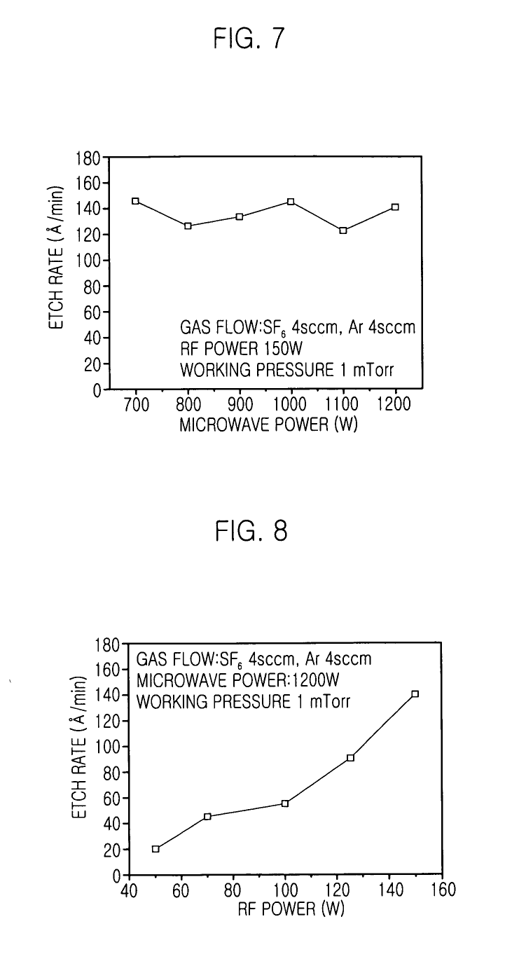

FIG. 7 illustrates a graph showing etch rates of platinum according to various microwave power levels. The etch rates according to the various microwave power levels do not show significant changes. This result is generated because a sufficient amount of radicals needed for etching is formed at a microwave power of approximately 700 W or higher.

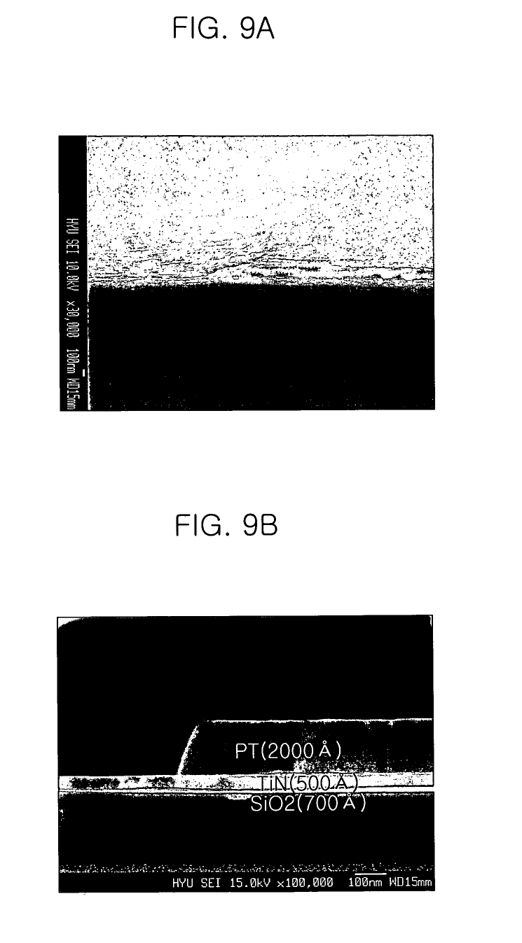

FIG. 8 illustrates a graph showing etch rates of platinum according to various radio frequency (RF) power levels. The etch rate increases as the RF power level increases. Generally, density of plasmas increases as RF bias power increases. Thus, incident ion flux increases, resulting in increased etch rates. Observed results of etched surfaces of platinum using the above-described etch characteristics are shown in FIGS. 9A and 9B.

FIG. 9A illustrates a micrographic view of an etched surface of a platinum layer using Cl₂/Ar gas. FIG. 9B illustrates a micrographic view of an etched surface of another platinum layer using SF₆/Ar gas. The other platinum layer etched by SF₆/Ar gas shows an enhanced pattern with a sidewall slope of approximately 70° when compared to the platinum layer etched by Cl₂/Ar gas. That is, tapering is reduced. Surface roughness of platinum is compared below.

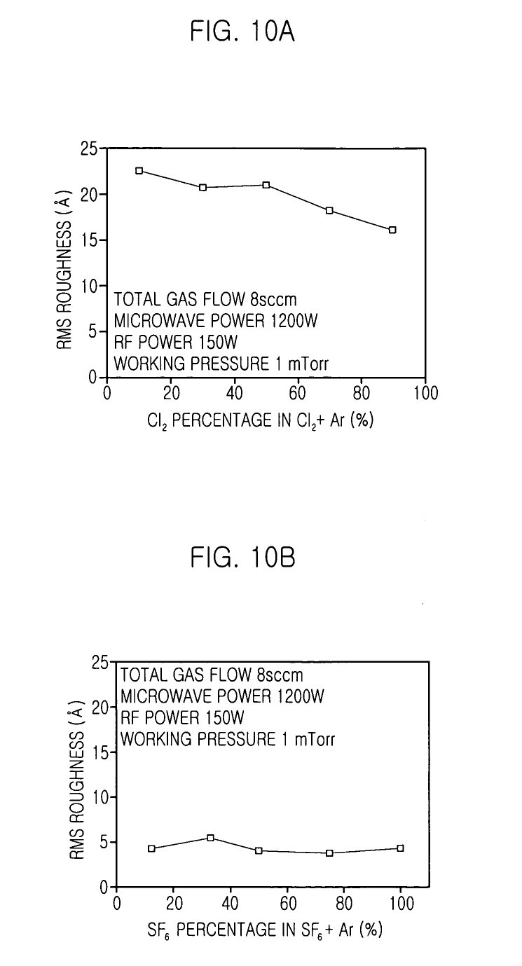

FIG. 10A illustrates a graph showing surface roughness of platinum that is etched using a gas mixture including Cl₂/Ar. FIG. 10B illustrates a graph showing surface roughness of platinum that is etched using a gas mixture including SF₆/Ar. Results shown in FIGS. 10A and 10B are obtained by using the following conditions. A total flow rate of the gas mixture is approximately 8 sccm, and a microwave power of approximately 1,200 W, a RF bias power of approximately 150 W, and a pressure of approximately 1 mTorr are used. The surface roughness is expressed in root mean square (RMS) using an atomic force microscope (AFM). The graph in FIG. 10A illustrates changes in surface roughness according to various content levels of Cl₂, and the graph in FIG. 10B illustrates changes in surface roughness according to various content levels of SF₆.

Comparison between the graphs in FIGS. 10A and 10B are described in the following. The platinum etched using the gas mixture including SF₆/Ar indicates lower surface roughness values than that of the platinum etched using the gas mixture including Cl₂/Ar. That is, the surface roughness of the platinum etched using the gas mixture including Cl₂/Ar ranges from approximately 17 Å to approximately 23 Å, while the surface roughness of the platinum etched using the gas mixture including SF₆/Ar ranges from approximately 3 Å to approximately 5 Å.

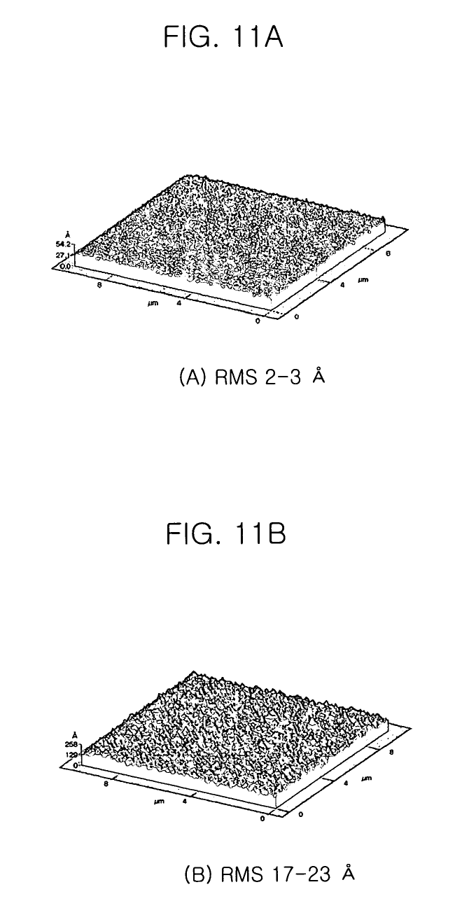

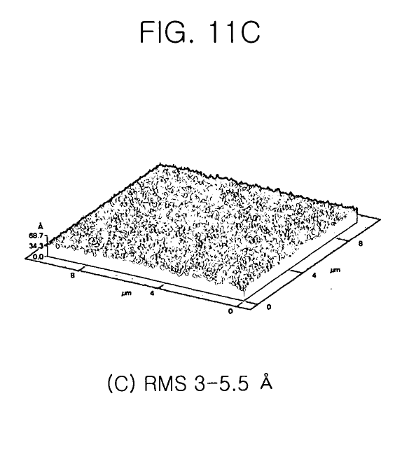

FIGS. 11A to 11C illustrate atomic force microscopic (AFM) views of etched platinum surfaces. FIG. 11A shows an image of a virgin platinum layer with a surface roughness RMS ranging from approximately 2 Å to approximately 3 Å. FIG. 11B shows an image of a platinum layer with a surface roughness RMS ranging from approximately 17 Å to approximately 23 Å, etched using a gas mixture including Cl₂/Ar. FIG. 11C shows an image of a platinum layer with a surface roughness RMS ranging from approximately 3 Å to approximately 5.5 Å, etched using a gas mixture including SF₆/Ar. Referring to FIGS. 11A to 11C, surface roughness is evenly spread over the platinum layer.

Referring to FIGS. 10A and 10B and FIGS. 11A to 11C, the platinum layer etched using the gas mixture including Cl₂/Ar shows high surface roughness ranging from approximately 17 Å to approximately 23 Å because non-volatile compounds are deposited on the surfaces of the platinum layer, increasing the surface roughness.

On the contrary, the platinum layer etched using the gas mixture including SF₆/Ar shows low surface roughness because volatile compounds are formed from reactions between the gas mixture and the platinum layer. The volatile compounds are not deposited on the surfaces of the platinum layer, decreasing the surface roughness.

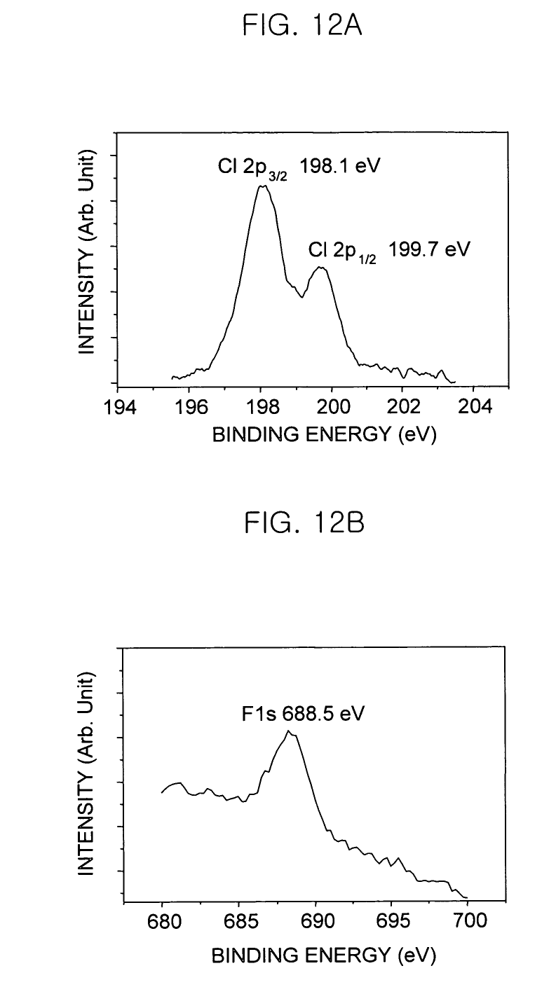

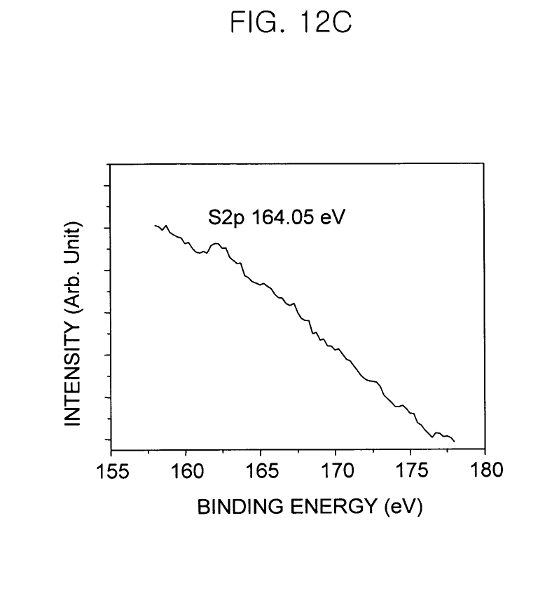

A platinum layer that is not patterned is exposed to a plasma as is the case in an etching process and an X-ray photoelectron spectroscopy (XPS) analysis is made on the platinum layer. The XPS analysis is executed to identify compound formation during an etching process through a surface analysis after etching. The XPS analysis is performed under the following principle. An X-ray is radiated on a sample ore to be analyzed. Then, each of composing atoms of the sample ore absorbs the X-ray and emits electrons. At this time, if the electrons are detected through a detector, kinetic energy can be obtained by subtracting binding energy of the electrons from input energy. That is, the binding energy of the electrons can be obtained by detecting the kinetic energy. Thus, composing elements of the sample ore can be identified because the binding energy has a specific value for each element. Furthermore, there may exist some movements of the binding energy according to a surrounding environment during the emission of the electrons, and thus, forms of chemical bonds may be identified. Results of the XPS analysis are shown in FIGS. 12A to 12C.

FIG. 12A illustrates a graph showing an XPS spectrum of a platinum surface etched using a gas mixture including Cl₂/Ar. FIGS. 12B to 12C illustrate graphs showing XPS spectrums of platinum surfaces etched using a gas mixture including SF₆/Ar.

Referring to FIG. 12A, a peak ‘Cl 2p’ is identified when the gas mixture including Cl₂/Ar is used for etching. Referring to FIG. 12B, a peak ‘F 1s’ is weakly generated at a narrow scan when the gas mixture including SF₆/Ar is used for etching. Referring to FIG. 12C, a peak ‘S 2p’ is hardly detected. This result is generated because sulfur reacts with platinum on surfaces and is volatilized.

Deriving from the results shown in FIGS. 12A to 12C, platinum fluoride compounds are formed when the gas mixture including SF₆/Ar is used for etching because a fluorine peak is weakly formed on the platinum surface. SF₆ gas contributes to the etching of platinum and generates volatile compounds. Thus, surface roughness does not increase.

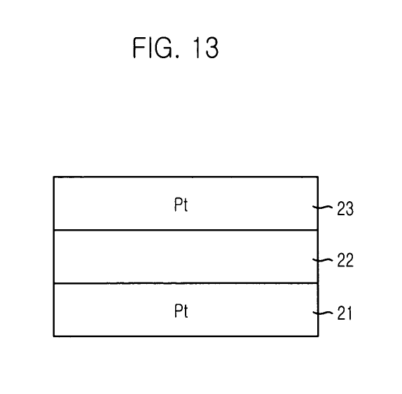

FIG. 13 illustrates a cross-sectional view showing a method for forming a capacitor using platinum layers as a bottom electrode and an upper electrode in accordance with a specific embodiment. A bottom electrode 21 includes a platinum layer. A dielectric layer 22 is formed over the bottom electrode 21. The dielectric layer 22 includes a high-k dielectric layer such as a lead-zirconate-titanate (PZT)-based dielectric layer or a barium-strontium-titanate (BST)-based dielectric layer. An upper electrode 23 is formed over the dielectric layer 22. The upper electrode 23 includes a platinum layer. The bottom electrode 21 may be formed in a flat, concave or cylinder structure. The platinum layers used as the bottom electrode 21 and the upper electrode 23 are generally required to be etched in a manner such that the platinum layers fit in each structure.

The bottom electrode 21 and the upper electrode 24 are formed by etching with a gas mixture including SF₆ gas, which includes fluorine, and Ar gas, which is an inert gas. Thus, tapering, a fence and surface roughness increase are reduced. Accordingly, a capacitor with improved reliability and restrained leakage current may be fabricated by improving etch characteristics of platinum, e.g., tapering, a fence, and surface roughness.

While the present invention has been described with respect to the specific embodiments, it will be apparent to those skilled in the art that various changes and modifications may be made without departing from the spirit and scope of the invention as defined in the following claims.

What is claimed is:

1. A method for etching platinum (Pt), comprising etching a platinum layer using a gas mixture including a fluorine (F) containing gas and an inert gas.

2. The method of claim 1, wherein the fluorine containing gas comprises sulfur hexafluoride (SF₆) gas and the inert gas comprises argon (Ar) gas.

3. The method of claim 2, wherein a ratio of a flow rate of SF₆ is approximately 50% of a flow rate of the gas mixture.

4. The method of claim 3, wherein etching the platinum layer comprises utilizing an etch apparatus using an electron cyclotron resonance (ECR) method.

5. The method of claim 4, wherein etching the platinum layer comprises using a pressure ranging from approximately 1 mTorr to approximately 5 mTorr, a microwave power ranging from approximately 700 W to approximately 1,200 W, and a radio frequency (RF) bias power ranging from approximately 100 W to approximately 150 W.

6. A method for fabricating a capacitor having a bottom electrode, a dielectric layer, and an upper electrode, the method comprising:
forming the bottom electrode by etching a platinum layer; and
forming the upper electrode by etching another platinum layer, wherein the platinum layers are etched using a gas mixture including a fluorine (F) containing gas and an inert gas.

7. The method of claim 6, wherein the fluorine containing gas comprises sulfur hexafluoride (SF₆) gas and the inert gas comprises argon (Ar) gas.

8. The method of claim 7, wherein a ratio of a flow rate of SF₆ is approximately 50% of a flow rate of the gas mixture.

9. The method of claim 8, wherein etching the platinum layers comprises utilizing an etch apparatus using an electron cyclotron resonance (ECR) method.

10. The method of claim 9, wherein etching the platinum layers comprises using a pressure ranging from approximately 1 mTorr to approximately 5 mTorr, a microwave power ranging from approximately 700 W to approximately 1,200 W, and a radio frequency (RF) bias power ranging from approximately 100 W to approximately 150 W.
